(19) United States
(12) Patent Application Publication
(10) Pub. No.: US 2010/0269889 A1
(43) Pub. Date: Oct. 28, 2010

(54) Photoelectric Solar Panel Electrical Safety System Permitting Access for Fire Suppression

(75) Inventors: Michael B. Reinhold, Laguna Niguel, CA (US); Antonio S. Rubino, Laguna Niguel, CA (US); Edmund R. Burke, Newport Beach, CA (US)

Correspondence Address: Law Offices of Daniel L. Dawes;Dawes Patent Law Group, 5200 Warner Blvd, Ste. 106, Huntington Beach, CA, 92649, US

(73) Assignee: MHLEED Inc., Dana Point, CA (US)

(21) Appl. No.: 12/430,793

(22) Filed: Apr. 27, 2009

(51) Int. Cl. H01L 31/048; B23P 19/00; H02J 1/00

(52) U.S. Cl. 136/251; 29/426.1; 307/86

(57) ABSTRACT

An apparatus and method is provided to allow fire fighters and other personnel unimpeded access to a roof no matter the placement or configuration of a plurality of solar panels installed on the roof. A user first disables the flow of electricity from the solar panels by activating a fail-safe system, thus electrically isolating each solar panel from a common power line and making safe manipulation of the solar panel possible. The user then unlocks the solar panel from its mounting frame by opening a latch and rotates the solar panel on the frame to expose the portion of the roof beneath the panel. The solar panel rotates over the end of the frame and remains coupled to the frame. With the solar panel swung out of the way, full and unimpeded access of the roof below the panel is now accessible to the firefighter.

### BACKGROUND OF THE INVENTION

1. Field of the Invention

The invention relates to the field of solar panels, in particular electrical fail-safe safety systems for a photoelectric solar panel array which allow roof access for fire suppression and other needs such as maintenance.

2. Description of the Prior Art

Photoelectric solar panels are typically used to generate usable electricity from solar energy and have been placed on nearly every structure from private homes to large commercial businesses and warehouses. A photoelectric solar panel array comprises an assembly of thousands of photocells arranged in an array of multiple panels. The output of a typical solar panel is between 200 and 300 W of electrical energy at 48 volts. When several of these panels when interconnected, they provide an excellent electric power source for the building on which they are installed thus reducing the amount of electricity purchased from utility companies and further providing power when service from remote utilities is interrupted. As solar panel technology continues to improve and becomes more cost efficient and as the cost of other sources of energy such as oil and natural gas continues to increase, the installation of photoelectric solar panel arrays will only become widespread.

However while solar panels are an eco-friendly and sustainable source of renewable energy, some significant drawbacks to their installation have come to the forefront. One among these drawbacks is that the installation and placement of the solar panels on the roofs of the structures on which they are installed significantly hinders or makes fire protection or suppression difficult or infeasible. For example, on a large square or rectangular shaped roof of a business, store, or warehouse, solar panels are placed close to one another in long aisles across the entirety of the roof. On some roofs the rows of solar panels are placed in arrays head to foot, almost making the entire roof a solid block of solar panels. While these configurations may be the most energy efficient, they make fire fighting and fire protection almost impossible since they severely limit access to the roof to any fire fighter wishing to climb to the roof and cut a ventilation hole to exhaust uncombusted volatile gases from the interior of the structure.

Typically in order to effectively fight a fire that has started in a structure, a hole or vent is cut in the roof over a hot spot in order to evacuate dangerous combustible gases from the building and thus allow other fire fighters to enter the building at the ground level and begin extinguishing the fire. The ventilation hole and exhaustion of trapped volatile gases prevents an explosive flashback when the structure is entered and air is suddenly allowed to mix with the gases that might otherwise be trapped within the structure, but for the ventilation hole. If free roof access is denied to the fire fighter because of the solar panel array installation, then the ventilation hole needed in the roof cannot be cut. Additionally, even if a fire fighter is capable of traversing the roof, if a hot spot is located underneath a solar panel or group of solar panels, the fire fighter cannot cut through the roof because of the solar panel blocks access to where the ventilation hole needs to be cut.

Furthermore, if a fire fighter attempts to cut through the solar panel in order to get to the roof, a significant chance of electrocution is present. As mentioned above, the output of a typical solar panel that is 6′×3′ or 8′×4′ in area is between 200 and 300 W of power at 48 volts. While this amount of electrical energy is below the threshold of being dangerous, interconnecting a plurality of solar panels quickly increases the power or amperage. For example, just four typical solar panels coupled together can deliver up to 600 W at 96 volts, a value which is at or above the hazardous and life threatening threshold. A typical rooftop installation on an industrial or large commercial building could have several hundred solar panels, all interconnected and producing electrical power. Typically these panels are hardwired together and in such a case there exists an extremely hazardous situation for anyone on that roof such as repairmen, painters, cleaners and the like when the solar array is operating. If the panels are hardwired together, there is no way of switching them off and any time the sun is shining there is a hazardous amount of electrical energy being generated.

This problem is only enlarged when a fire is present in the building in which the solar panels are installed upon. As mentioned previously, if fire fighters need to open up a vent in the roof of the building, they may not be able to because cutting through a live solar panel network would expose them to dangerous amounts of electricity. In that situation, the fire fighters cannot safely enter the structure to fight the fire and have no option other than to simply let the building burn and are forced to use only defensive fire fighting techniques rather than aggressively attempting to extinguish the fire.

This then presents the problem with any large scale or commercial solar panel installation. Buildings with large amounts of solar panels installed on their roofs will become uninsurable, since solar panels greatly reduce the chances of any successful fire suppression and typically force a fire fighting unit to adopt a method of containment and let the building burn rather than offensively fighting the fire and perhaps save the building or minimize damage.

Therefore an apparatus and method is needed that allows fire fighters to gain unimpeded access to any part of a roof of a burning structure, regardless of solar panel placement and without the risk of electrocution from the solar panels themselves.

### BRIEF SUMMARY OF THE INVENTION

An apparatus and method is provided to allow fire fighters and other personnel unimpeded access to a roof no matter the placement or configuration of a plurality of solar panels installed on the roof. A user first disables the flow of electricity from the solar panels by activating a fail-safe system, thus electrically isolating each solar panel from a common power line and making safe manipulation of the solar panel possible. The user then unlocks the solar panel from its mounting frame by opening a latch and rotates the solar panel on the frame to expose the portion of the roof beneath the panel. The solar panel rotates over the end of the frame and remains coupled to the frame. With the solar panel swung out of the way, full and unimpeded access of the roof below the panel is now accessible to the firefighter.

More particularly, the illustrated embodiment of the invention is an apparatus for mounting a photoelectric solar panel on a supporting surface which includes a frame coupled to the solar panel, a stand for supporting the frame wherein the stand includes a rear section and a front section, a mechanism for coupling the frame to the rear section of the stand so that the frame may be rotated about the rear section of the stand to expose the surface beneath the solar panel, and a mechanism for selectively coupling the frame to the front section of the elevated stand.

The frame includes an adjustable frame having a length and a width, and wherein the frame is adjustable in both of its length and width to accommodate the solar panel.

The mechanism for coupling the frame to the front section of the stand includes a rotatable latch to selectively lock the frame to the front section of the stand.

The mechanism for coupling the frame to the rear section of the stand includes a pair of hinges adapted to cantilever the frame and the solar panel over the rear of the stand to substantially expose the surface over which the solar panel was disposed.

The frame is coupled to the solar panel by a plurality of brackets.

The stand elevates the solar panel above the surface at a predetermined angle of inclination for optimal average solar incidence.

In another aspect the illustrated embodiment of the invention is an apparatus for electrically isolating a plurality of photovoltaic solar panels from a common power line comprising a plurality of switching circuits with at least one switching circuit coupled to each corresponding one of a plurality of solar panels, and a master controller coupled to the plurality of switching circuits by a control line. It is to be understood that switching circuits is meant to include relays, diode circuits, transistor circuits or any other circuit or device which is capable of electrically isolating the panel from the common power line. The master controller opens each of the switching circuits upon the detection of a fire alarm to disconnect each of the solar panels from the common power line. An uninterrupted power supply is coupled to the master controller and fire alarm detection circuit.

The apparatus further includes an amplifier having its input coupled to the master controller via the control line and its output coupled to selected ones of the switching circuits to extend the number of switching circuits which may be controlled by the master controller.

The uninterrupted power supply is coupled to the amplifier or further comprising another uninterrupted power supply coupled to the amplifier.

The master controller includes an isolation circuit for controlling the plurality of switching circuits coupled to the plurality of solar panels to selectively disconnecting each solar panel from the common power line upon detection of a fire alarm or other emergency event, a detector circuit coupled to the isolation circuit for detecting the fire alarm or other emergency event, and an isolation reset circuit coupled to the isolation circuit for receiving reset instructions from a user and for selectively resetting the isolation circuit after it has disconnected each solar panel from the common power line to reconnect each solar panel to the common power line.

The apparatus further includes an alarm and an alarm circuit coupled to the detector circuit for generating a signal that a fire alarm or other emergency event has been detected by the detector circuit to activate the alarm.

The master controller further includes an isolation reset controller coupled to the isolation reset circuit and wherein the isolation reset controller includes mechanism for inputting a manual, multi-step process for resetting the isolation circuit to selectively reconnect the plurality of solar panels to the common power line via the corresponding plurality of switching circuits.

The master controller further includes a timer coupled to the isolation circuit and wherein the timer triggers and resets the isolation circuit on a periodic basis to cycle the plurality of switching circuits through an open and closed configuration.

The illustrated embodiment includes the combination of the electrical system described above with the mounting system for the solar panels described above.

In another aspect, the illustrated embodiments of the invention is a method of gaining safe access to a surface beneath a plurality of solar panels including the steps of automatically electrically isolating the plurality of solar panels from a common utility power line and from each other on the event of a fire alarm or other emergency event, releasing at least one solar panel from a front section of a stand on which the solar panel is mounted above the surface, and rotating the at least one solar panel about a rear section of the stand to expose the surface beneath the at least one solar panel.

The step of automatically electrically isolating the plurality of solar panels from a common utility power line and from each other on the event of a fire alarm or other emergency event includes the steps of detecting a fire alarm or other emergency event, and upon the detection of the fire alarm or other emergency event automatically cutting power from an isolation circuit to a plurality of switching circuits which couple the plurality of solar panels to the common utility power line to open the switching circuits and thus disconnect the plurality of solar panels from the common utility power line.

The step of releasing at least one solar panel from the front section of a stand includes the step of rotating a latch coupled to the solar panel so that the solar panel is unlocked or disconnected from the front section of the stand.

The step of rotating the at least one solar panel about a rear section of the stand to expose the surface beneath the at least one solar panel further includes the step of cantilevering the solar panel over the rear section of the stand to provide clear and unobstructed access to the portion of the surface beneath the at least one solar panel.

The method further includes the step of electrically reconnecting the plurality of solar panels to the common utility power line includes manually inputting a predetermined series of commands into an isolation reset controller coupled to an isolation circuit to resupply current to a plurality of switching circuits coupled to the isolation circuit to reconnect the plurality of solar panels to the common utility power line.

The method further includes the step of periodically cycling the plurality of relay circuits through an open and closed configuration on a predetermined schedule via a timer to prevent contact lead fusing.

While the apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112 are to be accorded full statutory equivalents under 35 USC 112. The invention can be better visualized by turning now to the following drawings wherein like elements are referenced by like numerals.

### BRIEF DESCRIPTION OF THE DRAWINGS

FIG. 1 is an exploded perspective view of a solar panel frame according to an illustrated embodiment of the invention.

FIG. 2 is an enlarged perspective view of a lower portion of the solar panel frame of FIG. 1 further showing the construction of the frame with the internal components shown in broken lines.

FIG. 3 is a perspective view of the assembled solar panel frame of FIG. 1.

FIG. 4 is an enlarged perspective view of the latch mechanism and lower portion of the solar panel frame of FIG. 3 shown with the latch in the closed position and the frame in the closed configuration.

FIG. 5 is an enlarged perspective view of the latch mechanism and lower portion of the solar panel frame of FIG. 3 with the latch in the open position and the frame swung open.

FIG. 6 is an enlarged perspective view of the hinges and upper portion of the solar panel frame of FIG. 3 with the frame swung open.

FIG. 7 is a side plan view of the solar panel frame with the frame in the closed configuration as shown in solid outline and with the frame swung open as shown in dotted outline.

FIG. 8 is a schematic diagram of the fail safe solar panel safety system coupled to a plurality of solar panels forming an array.

FIG. 9 is a schematic diagram of the safety system controller that is coupled to the solar panels shown in FIG. 8.

FIG. 10 is an electrical schematic diagram of the complete fail safe control system wherein the controller of FIG. 9 is coupled to a plurality of arrays of solar panels of FIG. 8.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE PREFERRED EMBODIMENTS

The illustrated embodiment of the current device and method allows fire fighters, maintenance workers and other personnel unimpeded access to a roof or other installation site of the solar array no matter the placement or configuration of a plurality of solar panels installed on the roof or site. A user first disables the flow of electricity from the solar panels by activating a fail-safe system, thus electrically isolating each solar panel from the system and making manipulation of the solar panel safely feasible. The user then approaches the solar panel and unlocks the panel from its frame by opening a latch mechanism and swings the solar panel open on its mounting frame. The solar panel swings and remains coupled to the frame via a set of hinges. With the solar panel swung out of the way, full and unimpeded access of the roof below is granted to the user.

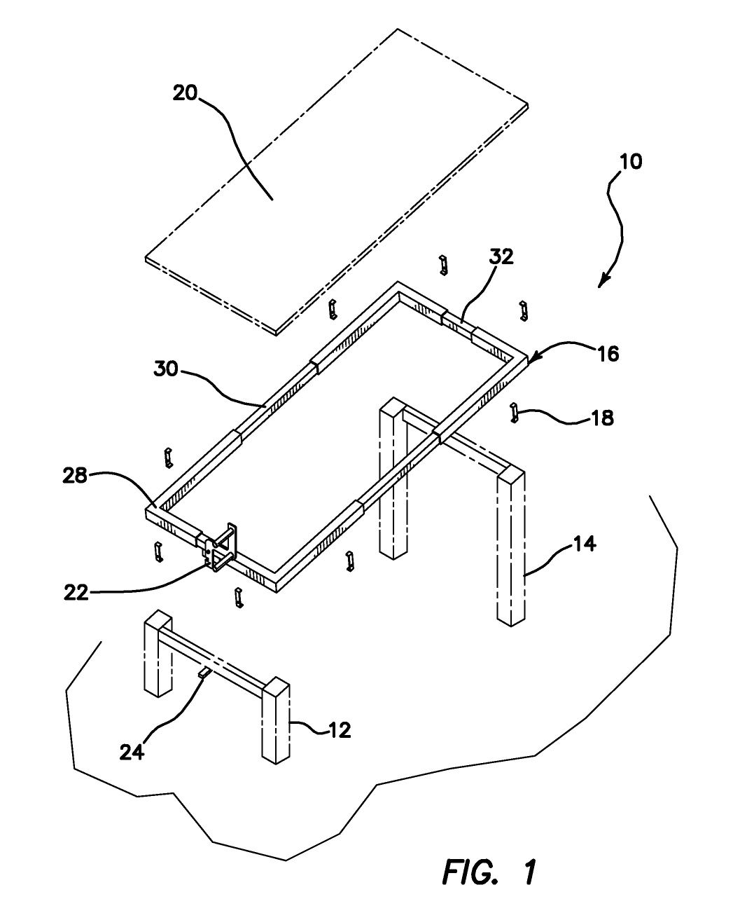

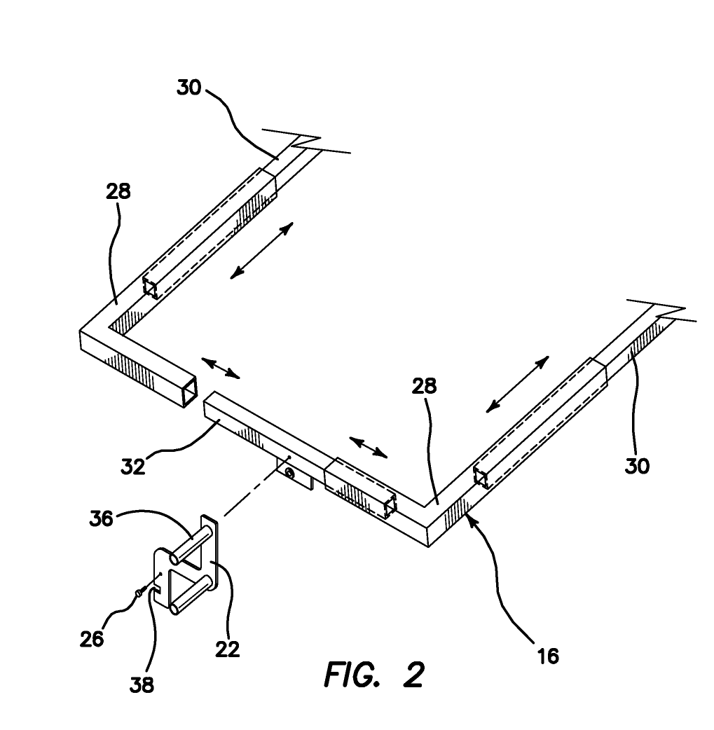

Further understanding of the disclosed method and apparatus can be obtained by turning to FIG. 1 which shows the solar panel frame assembly, generally denoted by reference numeral 10, and its various components. As seen in FIG. 1 the solar panel frame assembly 10 comprises a fully adjustable and universal frame 16. The frame 16 is substantially rectangular in shape to receive the rectangular shape of a photoelectric solar panel 20, however other shapes may used without departing from the original spirit and scope of the invention. The frame 16 is preferably made out of a durable metal or composite, however other materials such as plastic may also be effectively used. The frame 16 is comprised of several hollow interlocking pieces as best seen in FIG. 2 including four corner components 28, two side components 30, and two end components 32. In the illustrated embodiment corner components 28 are fabricated from hollow square bar. Side and end components 30 and 32 are similarly made from square hollow or solid bar. The four corner components 28 have slightly larger interior cross section than that of the side components 30 and end components 32 to allow the easy telescopic insertion of the side components 30 and end components 32 into the corner components 28 as seen in FIG. 2. The side and end components 30, 32 are sized to easily slide into the corner components 28 without excessive force and yet are large enough to provide a reasonably snug fit between them and the inner surfaces of the corner components 28.

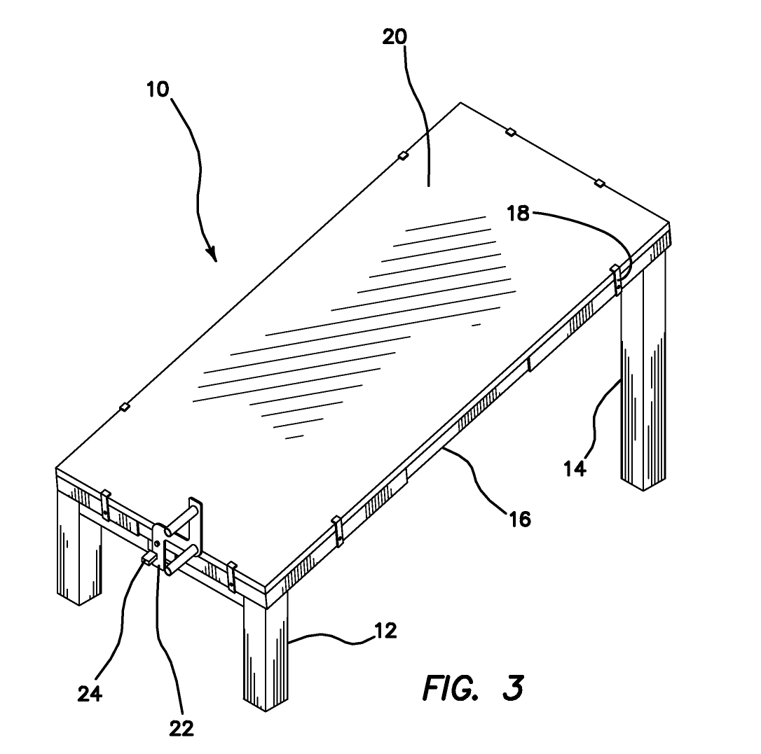

The frame 16 and its components allow for the adjustability and universality of the frame. If solar panel 20 is too large or small to be received by the frame 16 in one configuration, the side components 30 are either slid further into or out of the corner components 28 until the length of the frame 16 matches the length of the solar panel 20. A similar process is repeated with the end components 32 to match the width of frame 16 to that of the solar panel 20. When the correct length and width have been achieved, a plurality of brackets 18 are disposed around the frame 16 and solar panel 20 to couple the solar panel 20 to the frame 16 as best seen in FIG. 3. Brackets 18 may be rigid and be fixed to frame 16 by fasteners such a rivets, bolts or screws, or may be resilient and used to compressively clip panel 20 to frame 16 or both. While eight brackets 18 have been shown in FIGS. 1 and 3, this is meant to be for illustrative purposes only. Additional or fewer brackets 18 may be used, or alternatively, other means of coupling the solar panel 20 to the frame 16 may be used such as screws, clamps, or welds without departing from the original spirit and scope of the invention.

Also seen in FIG. 2 is a latch mechanism 22 that is coupled to the frame 16. The latch 22 is coupled to the frame 16 by a pin or bolt 26. The bolt 26 allows the latch 22 to freely rotate about the axis of the bolt 26 without significant effort on the part of a user. The latch 22 also comprises a pair of oversized pins 36. The pins 36 are oversized so as to allow a fireman's tool or pike to quickly engage pins 36 and rotate the latch 22 in an efficient manner. Additionally, the latch 22 includes a slot 38 defined into the lower portion of the latch 22 itself as depicted in FIG. 2, which engages with key 24 described below.

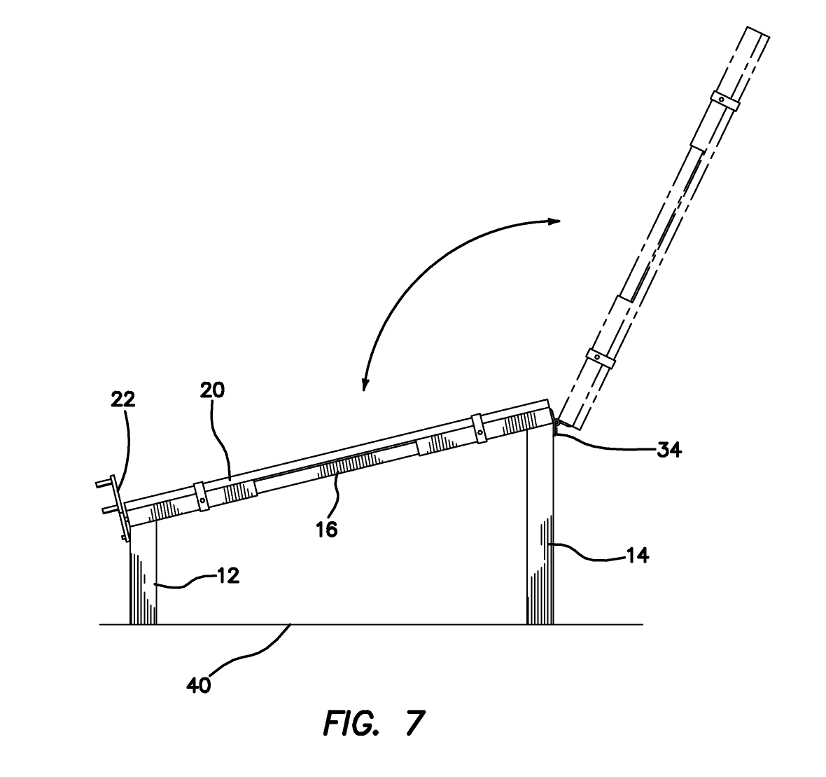

Turning now to FIG. 3, the frame 16 and solar panel 20 are positioned above the roof or installation surface by a pair of front legs 12 and a pair of back legs 14. The legs 12 and 14 may be made out of any durable, light weight material including but not limited to metal, metal composites, wood, or plastic. The legs 12 and 14 together therefore form an elevated stand for the frame 16 and solar panel 20 for ease of access to panel 20 and to incline panel 20 at a predetermined angle for optimum average solar exposure dependent on the latitude of the installation site. In FIG. 7, it is seen that the front legs 12 are shorter than the back legs 14 which causes the frame 16 and solar panel 20 to be positioned at an angle. This allows the solar panel 20 to be positioned at a maximum angle so as to be the most efficient while collecting energy from the sun. However the configuration of the legs 12, 14 shown in FIGS. 1-7 is for illustrative purposes only. It is to be expressly understood that the front legs 12 and back legs 14 may be at any number of different heights or configurations so as to angle the solar panel 20 to the best possible position to collect energy from the sun without departing from the spirit and scope of the invention. The preferred embodiment is to position latch 22 at the lower end of frame 16 so that gravity tends to retain panel 20 in a closed position, even if latch 22 is not in the locked or closed configuration.

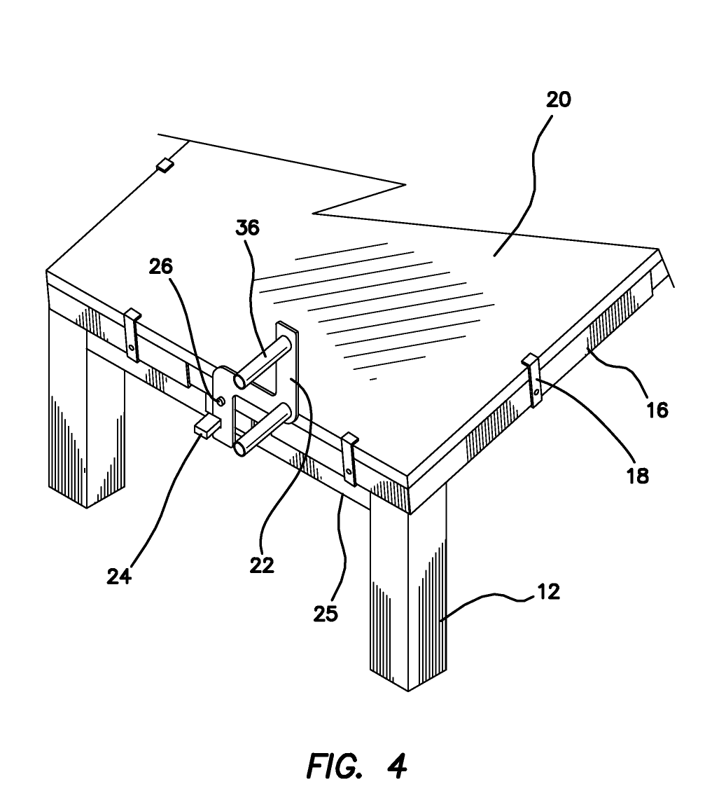

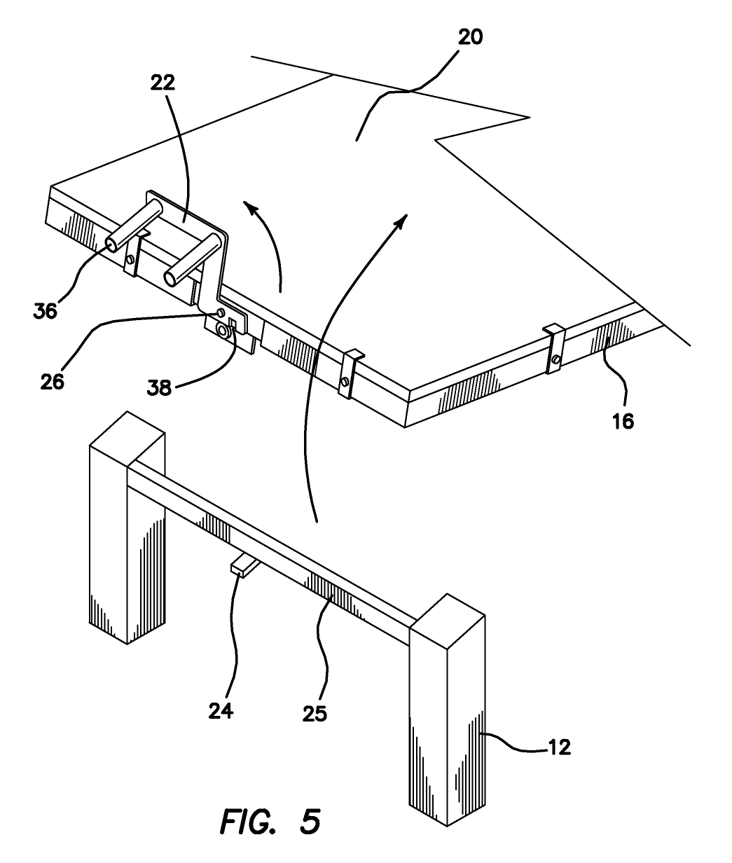

The frame 16 and solar panel 20 are selectively locked to a cross piece 25, best seen in FIG. 5, extending between the pair of the front legs 12 by the latch 22 coupled to the frame 16 as seen in FIG. 4. A key 24 is coupled to cross piece 25 by a weld or other similar means. The key 24 is made of a strong, light weight material such as metal or metal composite and is sized and shaped to fit within the slot 38 of the latch 22. With the key 24 fit into the slot 38 of the latch 22, the latch 22 is in the “locked” position and the frame 16 and solar panel 20 are selectively fixed to the front legs 12, which may either rest on the roof or site surface or be fixed thereto by conventional means not shown. Additionally, because of the shape of the slot 38 defined in the latch 22, the latch 22 is prevented from rotating in the clockwise direction in FIG. 4 and thus prevented any unintentional decoupling of the frame 16 from the cross piece 25 and front legs 12. In the figures it is shown that the key 24 and slot 38 are each substantially rectangular in shape, however any shape or shapes may be used without departing from the original spirit and scope of the invention.

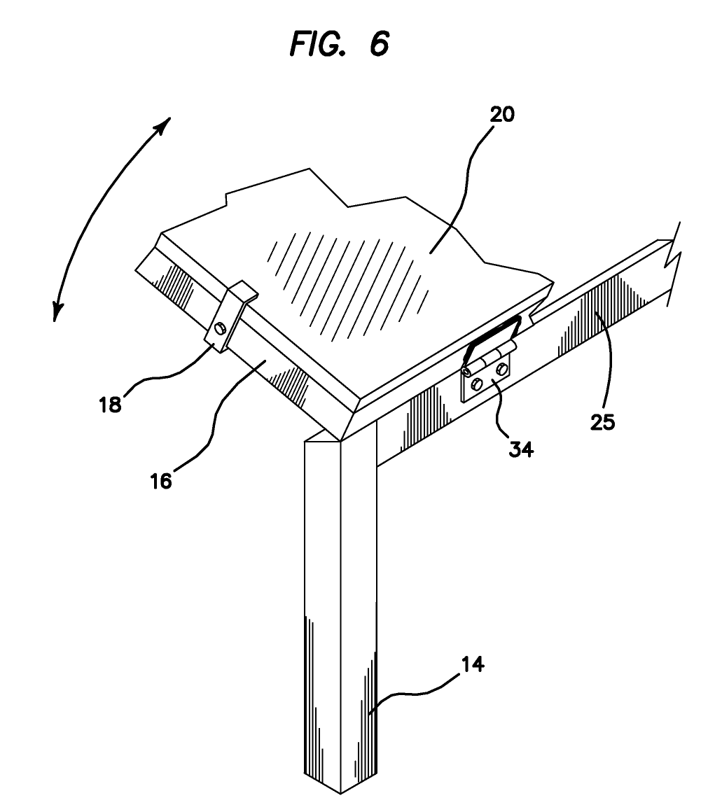

To decouple the frame 16 and solar panel 20 from the front legs 12, the user rotates the latch 22 counterclockwise in FIG. 4 about the axis of the bolt 26 as illustrated in FIG. 5. As the latch 22 rotates, the slot 38 is removed from the stationary key 24. Once the slot 38 is clear of the key 24, the frame 16 and solar panel 20 may then be lifted freely off of the front legs 12 using the pins 36 on the latch 22 or other means. As shown in FIG. 6 the frame 16 is coupled to the back legs 14 at the rear of the assembly 10 via a set of hinges 34. When the frame 16 is lifted upward off of the front legs 12, the hinges 34 allow the frame 16 and solar panel 20 to rotate and swing out of the way of the user and yet remained coupled to the back legs 14 as seen in the broken line drawing of FIG. 7. The hinges 34 are sufficiently strong enough to cantilever the frame 16 and solar panel 20 out in space and out of the immediate work space of the user. When the frame 16 and solar panel 20 are fully swung out of the way as seen in FIG. 7, the weight of the frame 16 and solar panel 20 keep them in a stationary position out over the back legs 14 thus allowing the user to gain unlimited access to a roof 40 located directly beneath where the solar panel 20 was originally disposed over. If the user wishes to return the solar panel 20 to its original position, the user once again grabs the pins 36 on latch 22 and swings the frame 16 and solar panel 20 back down until the front of the frame 16 makes contact with the front legs 12. The latch 22 is then rotated clockwise about bolt 26 until the slot 38 is once again firmly disposed about the key 24.

Hinges 34 have been depicted in FIG. 6 as fixed hinges, but it is also contemplated within the scope of the invention that hinges 34 may be separable. In other words, hinge 34 may have a conventional construction which would the hinge to be separated into two pieces when opened by sliding one half of the hinge relative to the other half. This will allow panel 20 to be slid out of engagement with cross piece 25 if desired for ease of maintenance and replacement. However, the user also has the option of leaving the two hinge halves in engagement to simply leave panel 20 in the open configuration as shown in dotted outline in FIG. 7.

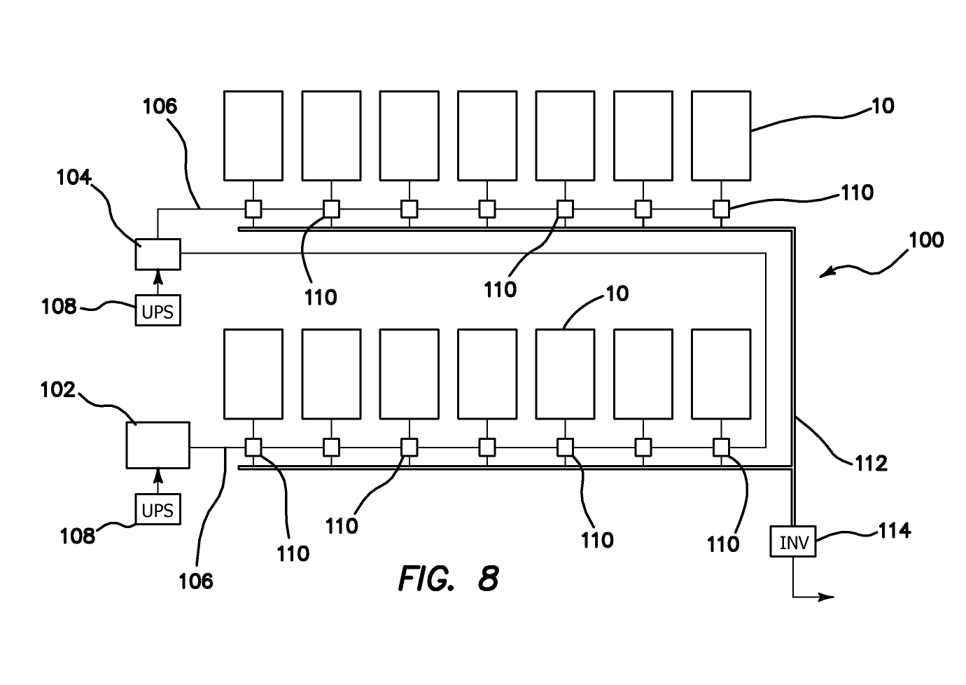

Turning now to FIG. 8, the fail safe system for electrically isolating the solar panels is depicted and generally noted by reference numeral 100. In FIG. 8, two banks of seven solar panel assemblies 10 each are shown by way of illustration. The number and arrangement of the panel assemblies 10 are arbitrary. A master controller 102 is coupled to the solar panel assemblies 10 in parallel via a control line 106. The master controller 102 is powered itself by an uninterrupted power supply (UPS) 108, such as a battery powered emergency power supply. The control line 106 is in turn coupled to each solar panel assembly 10 via a switching circuit 110. Power generated by each solar panel assembly 10 is sent through its corresponding switching circuit 110 and if the system is in operating mode and the switching circuit 110 is in the closed position, is then transmitted to the main power line 112 as a direct current. Power line 112 then leads to an inverter 114 which converts the direct current into an alternating current supplied to the building or site's electrical power input. Inverter 114 may include a regulator and frequency synchronizer to compensate for solar dependent output variations and utility line frequency respectively. Each solar panel assembly 10 coupled to the control line 106 contributes power in this manner so that the power that is received by the building is commercially practical. Switching circuit 110 may be incorporated within the envelope of solar panel assembly 10 or may be provided in a separate weatherproof housing and coupled to assembly 10 through a flexible cable. For example, switching circuit 110 may be mounted on the upper cross piece 25 near or in the vicinity of hinges 34 so that rotation of assembly 10 on frame 16 is allowed by the flexible cable coupling switching circuit 110 to assembly 10 without necessarily physically disconnecting or requiring the disconnection of the coupling of switching circuit 110 from assembly 10 in order to rotate panel assembly 10 to the fully open position.

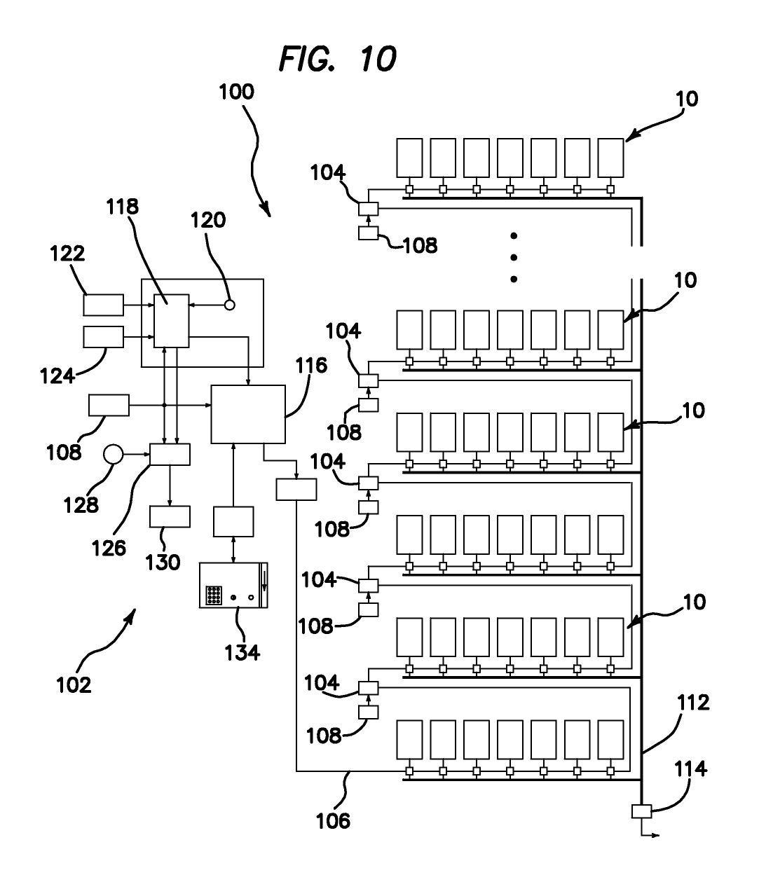

The control line 106 has a very low voltage and current running through it and therefore for configurations where several dozen or several hundred solar panels are needed, a signal amplifier 104 or a plurality of signal amplifiers 104 may be needed. In the example illustrated by FIG. 8, control line 106 is coupled to a number of solar panel assemblies 10 and then further coupled to a larger number of solar panel assemblies 10 through amplifier 104. Additional amplifiers may be added as the number of assemblies 10 is increased. Each signal amplifier 104 is powered by a corresponding dedicated UPS 108. However, it is to be understood that one or more UPS 108's may be shared among the amplifiers 104 and/or master controller. It is in this fashion that the master controller 102 may be coupled to large number of solar panel assemblies 10, provided that a signal amplifier 104 is coupled to the control line 106 at regular intervals according to the specifications of the control line 106 and the plurality of solar panel assemblies 10 as best seen in FIG. 10. It is also therefore to be expressly understood that the two banks of seven solar panel assemblies 10 each shown in FIG. 8 are meant to be for illustrative purposes only. Fewer or more banks may coupled to the master controller 102 than what is shown or alternatively, more or fewer solar panel assemblies 10 may comprise each bank than what is shown in FIG. 8 without departing from the original spirit and scope of the invention.

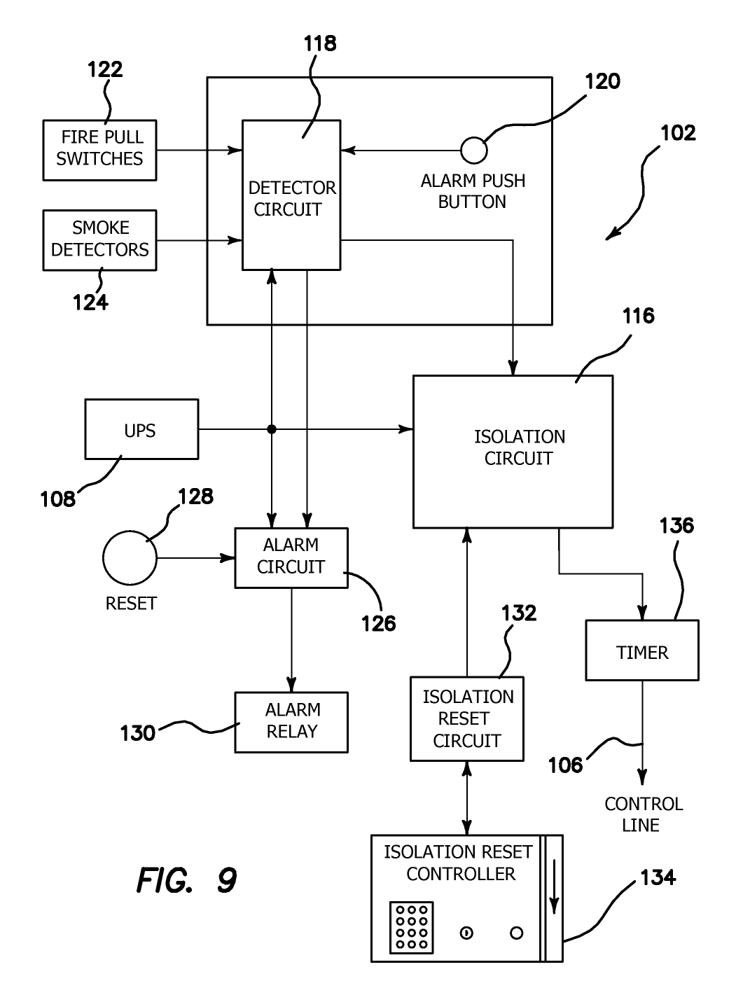

FIG. 9 depicts the master controller 102 in greater detail. The master controller 102 comprises three main components: an isolation circuit 116, a detector circuit 118, and an isolation reset circuit 132. The UPS 108 provides power to each of the isolation circuit 116, detector circuit 118, and isolation reset circuit 132. When a fire is present within a building in which the system 100 is installed in, a fire alarm is detected by the detection circuit 118 from one or more of a plurality of sources including any fire pull switch 122 being thrown in the building, one or more smoke or heat detectors 124 coupled to the detection circuit 118, or an alarm push button 120 on the master controller 102 itself. Once a fire alarm or other emergency has been detected, the detector circuit 118 sends a signal to the isolation circuit 116 and a separate signal to an alarm circuit 126. The signal sent to the alarm circuit 126 is in turn then sent to an alarm switching circuit 130 which then activates the building's warning system including any lights, sirens, or other emergency notification or fire suppression measures pre-existing within the building. The signal sent to the isolation circuit 116 in turn is sent through the control line 106 to all the switching circuits 110 present in the system 100. The switching circuit within each switching circuit 110 then opens up and disconnects the power flow from its corresponding solar panel assembly 10 to the power line 112, thus electrically isolating each solar panel assembly 10 from each other and isolating the main utility power supply from the system 100. Once activated, the system 100 will not reset automatically and the solar panel assemblies 10 will remain isolated until manually reset by the user.

With no power now flowing through the power line 112 and only a small amount of non-lethal power in each solar panel assembly 10, a fire fighter, maintenance person, or other personnel is free to safely manipulate the solar panel assemblies 10 at will, including swinging the frame 16 and solar panel 20 out of the way to gain access to the roof 40 as described above.

It is important to point out that the isolation circuit 116 provides the system 100 with a fail-safe method of operation, namely that should the UPS 108 fail or any other component of the master controller 102 fail, the system 100 is immediately triggered and all switching circuits 110 coupled to the master controller 102 are released and every solar panel assembly 10 is then electrically isolated or disconnected from power line 112. If the main utility supply fails however, the system 100 is left unaffected and continues to provide power to the building, and similarly, the system 100 does not interfere in any way with the utility electric supply when triggered.

When the fire or emergency is over or in cases where there was a false alarm, the user may reset alarm portion of the system by depressing a reset button 128 that is coupled to the alarm circuit 126 which is directly coupled to the detector circuit 118. The alarm circuit 126 then signals the alarm switching circuit 130 to turn off all lights, sirens, and other warning devices within the building. It should be noted that depressing the reset button 128 only terminates any alarm signals and does not reconnect any of the solar panel assemblies 10 to the power line 112.

In order to reset the switching circuits 110, reconnect assemblies 10 and thus resume power flow to the power line 112 and subsequently to the building, a deliberate and multi-step process must first be completed by the user. Coupled to the isolation circuit 116 is an Isolation reset circuit 132 which is in turn coupled to an isolation reset controller 134. After the condition that triggered the system 100 is no longer active or valid, the alarm reset button 128 must first be depressed shutting off all the buildings active alarms. Then the UPS 108 must be properly connected to the system 100 and switched on. The user may than use the isolation reset controller 134 by inserting and turning a reset key in the panel of the isolation reset controller 134. If detector circuit 118 is still active or detecting an alarm event, isolation circuit 116 cannot be reset. When the reset tone is heard, a reset button on the isolation reset controller 134 beside the reset key is pushed. The reset key may now be removed and the reset tone will become muted. At this point, the isolation reset circuit 132 sends a signal to the isolation circuit 116, which in turn provides current to the individual switching circuits 110 to close the switching circuits and thus resume power collected by the solar panel assemblies 10 to the power line 112. It is to be expressly understood that the sequence of procedures just described are meant for illustrative purposes only. Any number or variations of button pushing, insertion of keys, or other means such as the sliding of cards may be used so long as the process is manual and multi-step. The purpose of having a manual multi-step reset process is to ensure that the resuming of power flow in the system 100 is deliberate and purposeful. Having a reset process such as the one described above, which requires a very deliberate multistep reset procedure, cuts down the probability of accidents or other mistakes when a user believes that the system 100 is safely disconnected when in reality it may not be.

Finally, the master controller 102 comprises a timer mechanism 136 coupled to the isolation circuit 116. As is widely known in the art, contact leads such as those within the switching circuits 110 tend to fuse together if held closed and conducting for extended periods of time. The timer mechanism 136 cycles the contact leads open within the switching circuits 110 at regular intervals by sending a signal to the switching circuits 110 through the control line 106. The timer 136 preferably opens the switching circuits daily for a predetermined amount of time at night when the sun is not shining and power is not capable of being collected by the solar panel assemblies 10, however other cycling schedules or time periods may be used without departing from the original spirit and scope of the invention.

FIG. 10 depicts how the system 100 which comprises a plurality of banks of solar panel assemblies 10 may be coupled to a single master controller 102. FIG. 10 also shows how each bank is serviced by its own UPS 108 and signal amplifier 104.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following invention and its various embodiments.

Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed in above even when not initially claimed in such combinations. A teaching that two elements are combined in a claimed combination is further to be understood as also allowing for a claimed combination in which the two elements are not combined with each other, but may be used alone or combined in other combinations. The excision of any disclosed element of the invention is explicitly contemplated as within the scope of the invention.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptionally equivalent, what can be obviously substituted and also what essentially incorporates the essential idea of the invention.

We claim:

1. An apparatus for mounting a photoelectric solar panel on a supporting surface comprising:
a frame coupled to the solar panel;
a stand for supporting the frame wherein the stand comprises a rear section and a front section;
means for coupling the frame to the rear section of the stand so that the frame may be rotated about the rear section of the stand to expose the surface beneath the solar panel; and
means for selectively coupling the frame to the front section of the elevated stand.

2. The apparatus of claim 1 where the frame comprises an adjustable frame having a length and a width, and wherein the frame is adjustable in both of its length and width to accommodate the solar panel.

3. The apparatus of claim 1 where the means for coupling the frame to the front section of the stand comprises a rotatable latch to selectively lock the frame to the front section of the stand.

4. The apparatus of claim 1 where the means for coupling the frame to the rear section of the stand comprises a pair of hinges adapted to cantilever the frame and the solar panel over the rear of the stand to substantially expose the surface over which the solar panel was disposed.

5. The apparatus of claim 1 where the frame is coupled to the solar panel by a plurality of brackets.

6. The apparatus of claim 1 where the stand elevates the solar panel above the surface at a predetermined angle of inclination for optimal average solar incidence.

7. An apparatus for electrically isolating a plurality of photovoltaic solar panels from a common power line comprising:
a plurality of switching circuits with at least one switching circuit coupled to each corresponding one of a plurality of solar panels;
a master controller coupled to the plurality of switching circuits by a control line, the master controller opening each of the switching circuits upon the detection of a fire alarm to disconnect each of the solar panels from the common power line; and
an uninterrupted power supply coupled to the master controller and fire alarm detection circuit.

8. The apparatus of claim 7 further comprising an amplifier having its input coupled to the master controller via the control line and its output coupled to selected ones of the switching circuits to extend the number of switching circuits which may be controlled by the master controller.

9. The apparatus of claim 8 where the uninterrupted power supply is coupled to the amplifier or further comprising another uninterrupted power supply coupled to the amplifier.

10. The apparatus of claim 7 where the master controller comprises:
an isolation circuit for controlling the plurality of switching circuits coupled to the plurality of solar panels to selectively disconnecting each solar panel from the common power line upon detection of a fire alarm or other emergency event;
a detector circuit coupled to the isolation circuit for detecting the fire alarm or other emergency event; and
an isolation reset circuit coupled to the isolation circuit for receiving reset instructions from a user and for selectively resetting the isolation circuit after it has disconnected each solar panel from the common power line to reconnect each solar panel to the common power line.

11. The apparatus of claim 10 further comprising an alarm and an alarm circuit coupled to the detector circuit for generating a signal that a fire alarm or other emergency event has been detected by the detector circuit to activate the alarm.

12. The apparatus of claim 10 where the master controller further comprises an isolation reset controller coupled to the isolation reset circuit and wherein the isolation reset controller comprises means for inputting a manual, multi-step process for resetting the isolation circuit to selectively reconnect the plurality of solar panels to the common power line via the corresponding plurality of switching circuits.

13. The apparatus of claim 10 where the master controller further comprises a timer coupled to the isolation circuit and wherein the timer triggers and resets the isolation circuit on a periodic basis to cycle the plurality of switching circuits through an open and closed configuration.

14. The apparatus of claim 7 further comprising a mounting for each photoelectric solar panel on a supporting surface comprising:
a frame coupled to the solar panel;
a stand for supporting the frame wherein the stand comprises a rear section and a front section;
means for coupling the frame to the rear section of the stand so that the frame may be rotated about the rear section of the stand to expose the surface beneath the solar panel; and
means for selectively coupling the frame to the front section of the elevated stand.

15. A method of gaining safe access to a surface beneath a plurality of solar panels comprising:
automatically electrically isolating the plurality of solar panels from a common utility power line and from each other on the event of a fire alarm or other emergency event;
releasing at least one solar panel from a front section of a stand on which the solar panel is mounted above the surface; and
rotating the at least one solar panel about a rear section of the stand to expose the surface beneath the at least one solar panel.

16. The method of claim 15 where automatically electrically isolating the plurality of solar panels from a common utility power line and from each other on the event of a fire alarm or other emergency event comprises:
detecting a fire alarm or other emergency event; and
upon the detection of the fire alarm or other emergency event automatically cutting power from an isolation circuit to a plurality of switching circuits which couple the plurality of solar panels to the common utility power line to open the switching circuits and thus disconnect the plurality of solar panels from the common utility power line.

17. The method of claim 15 where releasing at least one solar panel from the front section of a stand comprises rotating a latch coupled to the solar panel so that the solar panel is unlocked or disconnected from the front section of the stand.

18. The method of claim 15 where rotating the at least one solar panel about a rear section of the stand to expose the surface beneath the at least one solar panel further comprises cantilevering the solar panel over the rear section of the stand to provide clear and unobstructed access to the portion of the surface beneath the at least one solar panel.

19. The method of claim 15 further comprising electrically reconnecting the plurality of solar panels to the common utility power line comprises manually inputting a predetermined series of commands into an isolation reset controller coupled to an isolation circuit to resupply current to a plurality of switching circuits coupled to the isolation circuit to reconnect the plurality of solar panels to the common utility power line.

20. The method of claim 19 where the switching circuit is a relay circuit and further comprising periodically cycling the plurality of relay circuits through an open and closed configuration on a predetermined schedule via a timer to prevent contact lead fusing.
